(19) United States
(12) Patent Application Publication
(10) Pub. No.: US 2006/0174817 A1
(43) Pub. Date: Aug. 10, 2006

(54) Process for producing a silicon single crystal with controlled carbon content

(75) Inventors: Rupert Krautbauer, Portland, OR (US); Erich Gmeilbauer, St. Pantaleon (AT); Robert Vorbuchner, Burghausen (DE)

Correspondence Address: BROOKS KUSHMAN P.C., 1000 TOWN CENTER, TWENTY-SECOND FLOOR, SOUTHFIELD, MI, 48075, US

(73) Assignee: Siltronic AG, Munich (DE)

(21) Appl. No.: 11/349,707

(22) Filed: Feb. 8, 2006

(30) Foreign Application Priority Data
Feb. 10, 2005 (DE) 10 2005 006 186.9

(51) Int. Cl. H01L 21/322

(52) U.S. Cl. 117/2

(57) ABSTRACT

Process for producing a silicon single crystal with controlled carbon content, polycrystalline silicon being melted in a crucible to form a silicon melt, a stream of inert gas with a flow rate being directed onto the melting polycrystalline silicon, and the single crystal is pulled from the melt in accordance with the Czochralski method, wherein the flow rate of the inert gas stream is controlled in order to set a concentration of carbon in the melt.

### BACKGROUND OF THE INVENTION

1. Field of the Invention

The invention relates to a process for producing a silicon single crystal with controlled carbon content, polycrystalline silicon being melted in a crucible to form a silicon melt, a stream of inert gas with a defined low rate being directed onto the melting polycrystalline silicon, and the single crystal pulled from the melt in accordance with the Czochralski method.

2. Background Art

It is known that carbon as an impurity in monocrystalline silicon may exhibit both disadvantageous and advantageous effects with regard to the suitability of the silicon for producing electronic components. In order to avoid disadvantageous effects of carbon, Japanese published application JP-05009097-A proposes reducing the concentration of carbon in the single crystal by melting polycrystalline silicon at a pressure which is lower than the pressure at which the single crystal is pulled. The advantageous effect of carbon to promote the formation of oxygen precipitates has engendered particular interest, because such oxygen precipitates bind metallic contaminants (internal gettering) and are thus able to keep these contaminants away from the regions of the silicon in which the electronic components are formed. The presence of carbon is desired, in particular, when the oxygen concentration is so low that the number of oxygen precipitates that form does not suffice for efficiently trapping metallic contaminants. This situation regularly occurs if the melt contains high concentrations of electrically active dopants of the n type, such as arsenic or antimony. Since a furnace in which a silicon single crystal is pulled according to the Czochralski method contains structures such as a resistance heating arrangement made of graphite surrounding the crucible, carbon in the form of oxidation products of the graphite passes inevitably but in uncontrolled fashion into the melt, and finally into the single crystal. However, efficiently controlling the formation of oxygen precipitates requires a process in which the concentration of the carbon in the melt can be controlled as precisely as possible. WO-01/06545 A2 therefore proposes adding a small quantity of carbon to the melt before a single crystal is pulled. This process requires additional outlay for a metering device and the operation thereof, for providing the carbon in the necessary purity and for homogeneously distributing the carbon in the melt. This additional outlay increases the costs of the process for producing the silicon single crystal.

### SUMMARY OF THE INVENTION

It is an object of the present invention to provide a process which makes it possible to establish a concentration of carbon in the melt and in the single crystal pulled therefrom, without any additional outlay in respect of time and materials which would be required by separately metering carbon to the melt. These and other objects are achieved by directing a stream of inert gas with a defined flow rate into the melting polysilicon prior to single crystal growth.

### BRIEF DESCRIPTION OF THE DRAWINGS

FIG. 1 illustrates one embodiment of a CZ crystal pulling apparatus suitable for use in the process of the invention.

FIG. 2 illustrates the effect of inert gas flow rate upon carbon content in a silicon melt prepared in accordance with one embodiment of the process of the invention.

### DETAILED DESCRIPTION OF THE PREFERRED EMBODIMENT(S)

The invention thus relates to a process for producing a silicon single crystal with controlled carbon content, by melting polycrystalline silicon in a crucible to form a silicon melt, a stream of inert gas with a defined flow rate being directed onto the melting polycrystalline silicon, followed by pulling a single crystal from the melt in accordance with the Czochralski method. In the process, the flow rate of the inert gas stream is controlled in order to establish a targeted concentration of carbon in the melt.

The inventors have surprisingly discovered that the carbon sources that are naturally present in the CZ furnace can be utilized for a controlled entry of carbon into the melt and into the single crystal. this incorporation of a targeted amount of carbon occurs during the portion of the production process in which polycrystalline silicon is melted in the crucible. In this portion of the process, the polycrystalline silicon contained in the crucible is flushed with an inert gas, preferably with argon, and the flow volume of inert gas is used for controlling the entry of carbon into the melt.

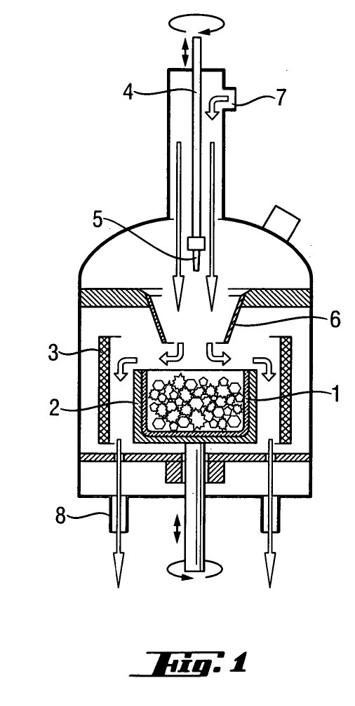

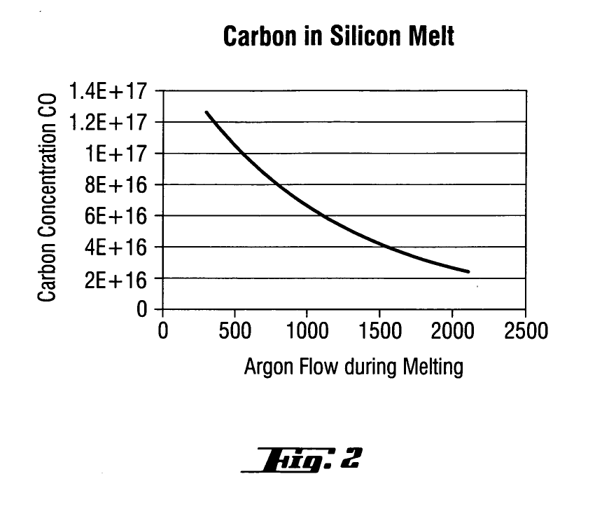

Details concerning the present invention are presented with reference to two figures. FIG. 1 schematically shows the construction of a furnace that is usually used for producing silicon single crystals according to the Czochralski method. FIG. 2 shows, in the form of a curve determined experimentally, the dependence of the concentration of carbon in the melt on the flow volume of inert gas.

As illustrated in FIG. 1, a furnace used for pulling silicon single crystals according to the Czochralski method contains a crucible 1, which initially contains polycrystalline silicon in the form of fragments and/or granules up to a specific filling level. The crucible is mounted on a shaft, and held in position by a susceptor 2. The susceptor is surrounded by a heating device 3, with the aid of which a silicon melt is produced from the polycrystalline silicon before the pulling of a single crystal is begun. Arranged at the upper end of the furnace is a mechanism, preferably a vertically moveable pulling shaft 4 or a cable pull, by means of which a seed crystal is lowered to the resulting melt and by means of which the single crystal growing on the seed crystal is rotated and lifted from the melt. A heat shield 6 is often fixed between the mechanism and an edge of the crucible. The heat shield shields the growing single crystal from the thermal radiation of the heating device, and conducts away an inert gas stream, introduced from gas inlet 7 onto the polycrystalline silicon and later onto the melt, to a gas outlet 8 in the furnace.

As revealed in FIG. 2, using the example of argon as the inert gas, the flow volume of inert gas during the melting of the single crystal has a crucial and controllable influence on the concentration of carbon in the melt produced. This is utilized according to the invention in order to establish a desired, or “targeted” concentration in the melt, and by taking account of the segregation coefficient of carbon, establishing the desired carbon content in the single crystal. The concentration of carbon in the melt at the beginning of crystal growth is preferably 1·10¹⁶ to 5·10¹⁷/cm³, corresponding to a concentration in the single crystal of preferably 1·10¹⁵ to 5·10¹⁷/cm³, (measured in accordance with ASTM method F 123-86). The concentration of carbon within the single crystal in this case rises greatly on account of the segregation within the crystal, so that the preferred concentration ranges for the seed end of the crystal are 1·10¹⁵ to 1·10¹⁷/cm³. While the polycrystalline silicon is melted, the flow volume of inert gas may be kept constant or varied. It is preferably 100 standard liters/hour to 10,000 standard liters/hour. The pressure is typically between 10 and 100 mbar.

The flow volume of inert gas is also influenced by parameters relating to the furnace and the components contained therein. It is therefore also possible, for example, to affect the carbon content of the melt in a targeted manner by means of these parameters, a variation (increase/reduction) associated with changing such a parameter being compensated by adjusting the flow volume of the inert gas flushing around the polycrystalline silicon thus providing a counter-variation (decrease/increase) in the carbon concentration in the melt. The most important of these furnace parameters are the dimensions and form of the furnace, of the heat shield, of the crucible, and of the susceptor, and also the relative position between the crucible and the pulling shaft. Further important parameters are the duration of the melting operation and the hot time, that is to say the duration of the phase after melting the polycrystalline silicon until the beginning of crystal pulling during which the established rate of flow of inert gas prevails. The entry of carbon into the melt can be increased further by means of a lengthened hot time. In particular, it is possible to control the carbon content over a wide concentration range by setting the temperature of the melt and/or the flow volume of inert gas during the hot time. However, a lengthened hot time is always associated with additional outlay in respect of time.

An additional means for influencing the concentration of carbon in the melt in a targeted manner consists of selecting a specific distance between the filling level (the area of polycrystalline silicon which is not delimited by the crucible) and the edge of the crucible, which is referred to below as the set-up height. Given a predetermined weighed-in quantity of polycrystalline silicon, the set-up height depends on the size of the fragments and/or the granules, it being smaller the larger the fragments. It has been found that the concentration of carbon in the melt becomes lower, the larger the set-up height. In order to obtain a low carbon content in the melt without having to accept a lower volume of the melt, it is possible, for example, to select a large set-up height by filling a comparatively small weighed-in quantity of large fragments into the crucible, and the volume of the melt produced after the melting of the fragments is increased by further polycrystalline silicon being charged to the melt and melted. It is likewise possible to control the filling level of the crucible given a fixed weighed-in quantity by means of the size distribution of the polysilicon. The suitable combination of different fragment sizes with granules and/or large polysilicon rod pieces makes it possible to adapt the set-up height for any arbitrary crucible form and size to the respective requirement.

While embodiments of the invention have been illustrated and described, it is not intended that these embodiments illustrate and describe all possible forms of the invention. Rather, the words used in the specification are words of description rather than limitation, and it is understood that various changes may be made without departing from the spirit and scope of the invention.

What is claimed is:

1. A process for producing a silicon single crystal with controlled carbon content, comprising melting polycrystalline silicon in a crucible to form a silicon melt, directing a stream of inert gas onto the melting polycrystalline silicon, and pulling a single crystal from the melt in accordance with the Czochralski method, wherein the flow rate of the inert gas stream is controlled, establishing a targeted concentration of carbon in the melt.

2. The process of claim 1, wherein the concentration of carbon in the melt is additionally controlled by adjusting the flow rate of the inert gas stream with respect to at least one parameter known to affect carbon content selected from the group consisting of the dimensions and form of a furnace in which the single crystal is pulled, the heat shield surrounding the single crystal, the crucible and the susceptor supporting it, and the relative position between the crucible and a pulling shaft.

3. The process of claim 1, wherein the concentration of carbon in the melt is additionally set by selecting a distance between a filling level of the polycrystalline silicon and an edge of the crucible prior to melting the polycrystalline silicon.

4. The process of claim 1, wherein the flow rate of the inert gas stream is controlled in such a way that 100 standard liters/hour to 1000 standard liters/hour of the inert gas stream flush around the polycrystalline silicon.

5. The process of claim 1, wherein a flow rate of argon is controlled in order to set the concentration of carbon in the melt.

6. The process of claim 1, wherein after melting the polysilicon and before the beginning of pulling the single crystal, for a specific duration, a temperature of the melt and/or the flow rate of the inert gas stream are controlled in order to set a concentration of carbon in the melt.

7. The process of claim 1 in which multiple furnaces of similar or identical design are employed, and a relationship between inert gas flow and carbon concentration in the melt is determined, the relationship being employed to establish a flow rate for a targeted carbon content in the melt.

8. The process of claim 7, wherein the relationship is established for a plurality of filling levels.

9. The process of claim 7, wherein a carbon concentration between 1·10¹⁶ to 5·10¹⁷/cm³ of melt is selected as a target carbon concentration, and a flow rate of inert gas which achieves this target concentration is introduced into the furnace.
